(19) United States
(12) Patent Application Publication
(10) Pub. No.: US 2025/0236822 A1
(43) Pub. Date: Jul. 24, 2025

(54) CLEANING COMPOSITION AND METHOD OF FORMING PHOTORESIST PATTERN USING THE SAME

(71) Applicant: DONGWOO FINE-CHEM CO., LTD., Jeollabuk-do (KR)

(72) Inventors: GI JIN KWUN, Jeollabuk-do (KR); BAEK HYUN CHO, Jeollabuk-do (KR); KYUNG HWA CHO, Jeollabuk-do (KR)

(21) Appl. No.: 19/013,564

(22) Filed: Jan. 8, 2025

(30) Foreign Application Priority Data
Jan. 23, 2024 (KR) 10-2024-0010186
Apr. 16, 2024 (KR) 10-2024-0050528

(51) Int. Cl. C11D 7/50; B08B 3/08; C11D 7/02; G03F 7/40

(52) U.S. Cl. CPC C11D 7/5022; B08B 3/08; C11D 7/02; G03F 7/40

(57) ABSTRACT

A cleaning composition includes an alcohol solvent and alloy particles. A content of the alloy particles is greater than 0 and 1 ppb or less based on a total weight of the composition. The alloy particles suppress the generation of impurities such as aldehyde and ketone, thereby reducing an occurrence of defects in manufacturing processes of semiconductor and display and improving yields.

### CROSS REFERENCE TO RELATED APPLICATION AND CLAIM OF PRIORITY

This application claims the benefit under 35 USC § 119 of Korean Patent Application Nos. 10-2024-0010186 filed on Jan. 23, 2024 and 10-2024-0050528 filed on Apr. 16, 2024 in the Korean Intellectual Property Office, the entire disclosure of which is incorporated herein by reference for all purposes.

### BACKGROUND

### 1. Field of the Invention

The present invention relates to a cleaning composition and a method of forming a photoresist pattern using the same.

### 2. Description of the Related Art

An alcohol solvent including isopropyl alcohol can be used for a purpose of cleaning an electronic device such as a semiconductor device, etc., or for a purpose of removing photoresist residues in photolithography during a manufacturing process of the semiconductor device.

For example, a semiconductor device or a high-resolution flat panel display having a fine line formed on a substrate can be manufactured by applying photoresist to the substrate, then exposing the substrate to light with a predetermined wavelength, followed by performing dry or wet etching thereon.

After forming a photoresist pattern by exposure and development processes, the residue remaining on the semiconductor substrate should be removed by a cleaning liquid. However, if micron-sized impurities exist in the cleaning liquid, the impurities may remain on a surface of the semiconductor device, thereby defects may occur.

To remove the photoresist pattern using the cleaning liquid, a cleaning liquid with high purity while suppressing an occurrence of impurities is required. For example, an antioxidant can be added to the cleaning liquid to suppress a generation of the impurities by an oxidation reaction of alcohol, but the antioxidant may contaminate the semiconductor substrate.

### SUMMARY

An object of the present invention is to provide a cleaning composition having improved temporal stability and detergency.

Another object of the present invention is to provide a method of forming a photoresist pattern using the cleaning composition.

To achieve the above objects, the following technical solutions are adopted in the present invention.

1. A cleaning composition including: an alcohol solvent; and alloy particles, wherein a content of the alloy particles is greater than 0 and 1 ppb or less based on a total weight of the composition.

2. In the cleaning composition, the alcohol solvent includes an alcohol having 2 to 5 carbon atoms.

3. In the cleaning composition, the alcohol solvent includes at least one selected from the group consisting of ethanol, 1-propanol, 2-propanol, 1-butanol and 1-pentanol.

4. In the cleaning composition, the alcohol solvent includes an alcohol having a boiling point of 110° C. or lower.

5. In the cleaning composition, the alloy particles include at least two selected from the group consisting of aluminum, nickel, iron, copper, zinc, cobalt, manganese, chromium, vanadium, titanium, zirconium, niobium, molybdenum, ruthenium, rhodium, silver and platinum.

6. In the cleaning composition, the alloy particles include at least two selected from the group consisting of nickel, aluminum, copper, iron, platinum and cobalt.

7. In the cleaning composition, the alloy particles include nickel, and further include at least one selected from the group consisting of aluminum, iron and copper.

8. In the cleaning composition, the alloy particles include aluminum, and further include at least one selected from the group consisting of nickel, iron and copper.

9. In the cleaning composition, the content of the alloy particles is 0.01 ppt or more and 0.5 ppb or less based on the total weight of the composition.

10. In the cleaning composition, the content of the alloy particles is 0.05 ppt or more and 0.1 ppb or less based on the total weight of the composition.

11. In the cleaning composition, the composition includes a balance of the alcohol solvent.

12. A method of forming a photoresist pattern including: forming a photoresist film on a substrate; partially removing the photoresist film to form a photoresist pattern; and cleaning the substrate on which the photoresist pattern is formed using the cleaning composition according to the above-described embodiments.

The cleaning liquid for a semiconductor substrate according to the embodiments of the present invention may include alloy particles in a predetermined content, and when the alcohol solvent included in the cleaning liquid is oxidized to form aldehyde and ketone, the formed aldehyde and ketone may be reduced to alcohol.

Therefore, when manufacturing an electronic device such as a semiconductor or display, it is possible to prevent an occurrence of impurities on the surface of the electronic device, and suppress an occurrence of defects, thereby improving a production yield of the electronic device.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 to 4 are schematic cross-sectional views for describing a method of forming a pattern according to exemplary embodiments.

### DETAILED DESCRIPTION

The embodiments of the present invention provide a cleaning composition including an alcohol solvent and alloy particles in a predetermined amount. Accordingly, the temporal stability and purity of the cleaning composition may be improved. In addition, a method of forming a photoresist pattern using the cleaning composition is provided.

As used herein, the abbreviation “ppb” means “parts-per-billion (10-9),” and the abbreviation “ppt” means “parts-per-trillion (10-12),” wherein the ppb and ppt may be based on the weight.

Hereinafter, embodiments of the present invention will be described in detail.

### <Cleaning Composition>

The cleaning composition (hereinafter, may be abbreviated as a composition) according to exemplary embodiments may include an alcohol solvent and alloy particles.

The alcohol solvent may remove process residues such as undeveloped photoresist or residual developer existing on a semiconductor substrate. For example, organic and inorganic residues existing between photoresist patterns after exposure and development may be effectively removed from the semiconductor substrate.

In some embodiments, the alcohol solvent may include an alcohol having 2 to 5 carbon atoms.

For example, the alcohol solvent may include at least one selected from the group consisting of ethanol, 1-propanol, 2-propanol, 1-butanol, 2-butanol, isobutanol, tert-butanol, 1-pentanol, 2-pentanol, 3-pentanol, 2-methyl-1-butanol, tert-amyl alcohol, 3-methyl-2-butanol, 3-methyl-1-butanol, and 2,2-dimethyl-1-propanol.

For example, methanol has high volatility thereby causing a deterioration in the detergency and stability, and an alcohol having greater than 5 carbon atoms may remain on a surface of the semiconductor substrate after cleaning. Accordingly, when the alcohol solvent includes an alcohol having 2 to 5 carbon atoms, an occurrence of defects during manufacturing a semiconductor device may be reduced.

According to exemplary embodiments, the alcohol solvent may be obtained by refining a crude oil. The purity of the alcohol solvent may be improved through the purification process.

For example, as the crude oil before purification, 2-propanol may be used as an alcohol solvent derived from fossil resources such as coal, oil, and natural gas, etc., and 2-propanol (bio-2-propanol) derived from biomass may be used.

Examples of bio-2-propanol may include 2-propanol obtained by using bacteria which produce 2-propanol from a biomass raw material (see International Patent Publication No. 2009/008377), 2-propanol obtained by hydrating propylene acquired by using biomethanol, 2-propanol obtained by reducing acetone acquired by using bioethanol, and 2-propanol obtained by hydrating propylene acquired by using bioethanol.

In some embodiments, the alcohol solvent may include a secondary alcohol. For example, examples of the secondary alcohol may include 2-propanol, 2-butanol, 2-pentanol, 3-pentanol, or 3-methyl-2-butanol, and preferably 2-propanol.

In some embodiments, the alcohol solvent may include at least one selected from the group consisting of ethanol, 1-propanol, 2-propanol, 1-butanol and 1-pentanol.

In some embodiments, the alcohol solvent may include at least one selected from the group consisting of ethanol, 1-propanol and 2-propanol.

For example, the alcohol having 2 or 3 carbon atoms has a low boiling point, thus it may not remain on the surface of the semiconductor substrate after cleaning. Accordingly, a yield of the manufactured semiconductor device may be increased.

In some embodiments, the alcohol solvent may include an alcohol having a boiling point of 110° C. or lower. For example, the alcohol having a boiling point of 110° C. or lower may include ethanol, 1-propanol, 2-propanol, 2-butanol, isobutanol, tert-butanol, or tert-amyl alcohol.

For example, the alcohol having a boiling point of 110° C. or lower is vaporized at a lower temperature, thus it may not remain on the surface of the semiconductor substrate after cleaning.

In some embodiments, the alcohol solvent may have a vapor pressure of 0.5 kPa or more at 25° C. For example, an alcohol having a vapor pressure of 0.5 kPa or more at 25° C. may include ethanol, 1-propanol, 2-propanol, 1-butanol, 2-butanol, isobutanol, tert-butanol, 2-pentanol, 3-pentanol, tert-amyl alcohol or 2,2-dimethyl-1-propanol.

For example, the alcohol having a vapor pressure of 0.5 kPa or more at 25° C. can be more easily vaporized, thus it may not remain on the surface of the semiconductor substrate after cleaning.

For example, the alcohol solvent may form impurities such as aldehyde and ketone by an oxidation reaction, and the impurities may grow into large particles having a large molecular weight and a micron size, thus they may remain on the surface of the semiconductor substrate after cleaning.

For example, the alloy particles may reduce the aldehyde and ketone formed by the oxidation reaction to alcohol. Accordingly, the temporal stability and purity of the cleaning composition may be improved.

In exemplary embodiments, a content of the alloy particles included in the cleaning composition may be greater than 0 and less than 5 ppb based on a total weight of the composition.

For example, when the cleaning composition does not include the alloy particles, impurities such as aldehyde and ketone may be formed by the above-described oxidation reaction, and residues may be formed on the surface of the semiconductor substrate after cleaning.

For example, when the content of the alloy particles is greater than 5 ppb, the alloy particles may remain on the surface of the semiconductor substrate after cleaning.

Accordingly, defects may occur during manufacturing an electronic device such a semiconductor or display, and a production yield of the electronic device may be reduced.

In some embodiments, the content of the alloy particles included in the cleaning composition may be 0.01 ppt or more and 0.5 ppb or less based on the total weight of the composition, for example, 0.05 ppt or more and 0.1 ppb or less, and may be 1 ppt to 50 ppt, 5 ppt to 30 ppt, 0.01 ppt to 500 ppt, 0.01 ppt to 100 ppt, 0.01 ppt to 10 ppt, or 0.05 ppt to 10 ppt.

Within the above range, the generation of impurities such as aldehyde and ketone may be suppressed, and the temporal stability and purity of the cleaning composition may be improved. Accordingly, the occurrence of defects during manufacturing the electronic device may be suppressed and the production yield may be improved.

For example, the alloy particles may include two or more metal elements of aluminum and transition metal elements. Accordingly, the aldehyde and ketone formed by the above-described oxidation reaction may be reduced to alcohol, and the temporal stability and purity of the cleaning composition may be improved.

For example, when the cleaning composition includes only one of the above-described metal elements, the aldehyde and ketone cannot be sufficiently reduced to alcohol, and residues may occur on the surface of the semiconductor substrate after cleaning. Therefore, defects may occur during manufacturing the electronic device such a semiconductor or display.

In some embodiments, the alloy particles may include at least two selected from the group consisting of aluminum, nickel, iron, copper, zinc, cobalt, manganese, chromium, vanadium, titanium, zirconium, niobium, molybdenum, ruthenium, rhodium, silver and platinum.

In some embodiments, the alloy particles may include at least two selected from the group consisting of nickel, aluminum, copper, iron, platinum and cobalt.

For example, the alloy particles may include: nickel and aluminum; nickel and iron; or platinum and cobalt.

For example, the alloy particles may include a nickel alloy. The nickel alloy may include nickel and at least one metal element of transition metal elements except for the aluminum and nickel.

In some embodiments, the alloy particles include nickel, and may further include at least one selected from the group consisting of aluminum, iron and copper. Accordingly, the above-described aldehyde and ketone may be sufficiently reduced to alcohol, and the temporal stability and purity of the cleaning composition may be improved.

For example, the alloy particles may include an aluminum alloy. The aluminum alloy may include at least one metal element of transition metal elements together with aluminum.

In some embodiments, the alloy particles include aluminum, and may further include at least one selected from the group consisting of nickel, iron and copper. Accordingly, the generation of impurities such as aldehyde and ketone may be suppressed, and the occurrence of defects during manufacturing the electronic device may be inhibited.

In some embodiments, the cleaning composition may include a balance of the alcohol solvent. For example, the cleaning composition may include alloy particles in the above-described content, and the balance of the alcohol solvent.

The term “balance” as used herein is used as a variable amount that can be changed depending on the addition of other components.

For example, the cleaning composition is adjusted by adding the alcohol solvent after appropriately adopting the above-described alloy particles according to specific needs, such that the balance of the entire composition is occupied by the alcohol solvent.

In one embodiment, the cleaning composition may include only one of the above-described alcohols as the alcohol solvent, or may include two or more of the above-described alcohols in combination thereof.

For example, when including two types of alcohols in combination, a content of one type of alcohol may be 10% by weight (“wt %”) to 70 wt %, 20 wt % to 60 wt %, or 30 wt % to 55 wt % based on the total weight of the composition, and another alcohol may be added in an amount corresponding to the balance of the cleaning composition.

### <Method of Forming Photoresist Pattern>

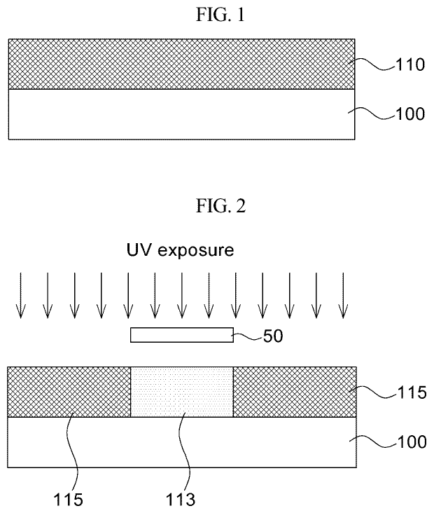

FIGS. 1 to 4 are schematic cross-sectional views for describing a method of forming a pattern according to exemplary embodiments. For example, FIGS. 1 to 4 illustrate a process for forming a pattern using a negative photoresist.

However, the cleaning composition according to exemplary embodiments is not limited to the process shown in FIGS. 1 to 4, and may also be utilized in a process for forming a pattern using a positive photoresist.

Referring to FIG. 1, a photoresist material may be applied to a substrate 100 to form a photoresist film 110.

The substrate 100 may include a semiconductor material such as single-crystal silicon or single-crystal germanium, and may also be formed to include polysilicon.

In some embodiments, after forming the photoresist film 110, a soft baking process may be performed. Accordingly, an organic solvent that can be included in the photoresist film 110 may be evaporated.

Referring to FIG. 2, a non-exposed part 113 and an exposed part 115 may be formed on the substrate 100 through an exposure process. The exposure process may be performed using a light source (e.g., an EUV light source) and an exposure mask 50.

The photoresist film 110 may be irradiated with light (e.g., EUV) passing through the exposure mask 50. Thereby, the photoresist film 110 may have the non-exposed part 113 and the exposed part 115.

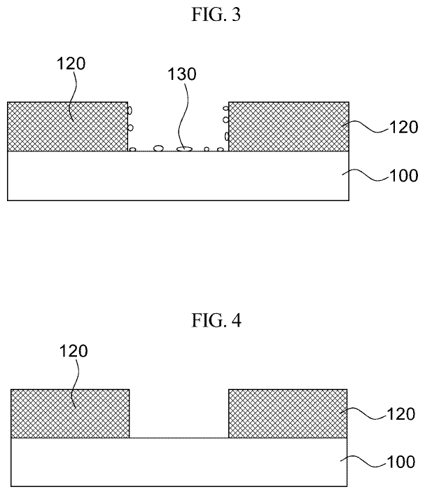

Referring to FIG. 3, a photoresist pattern 120 may be formed on the substrate 100 through a development process. For example, the photoresist patterns 120 composed of the exposed parts 115 may be formed by removing the non-exposed part 113 on the substrate 100 using a developer. The developer may be a tetramethylammonium hydroxide (TMAH) aqueous solution.

FIG. 3 illustrates process of forming a pattern using a negative photoresist, but it is not limited thereto. For example, a process of forming a pattern using a positive photoresist may be performed. In this case, the exposed part 115 may be removed and a photoresist pattern composed of the non-exposed part 113 may be formed.

In some embodiments, a post baking process may be further performed after the exposure process or after the development process.

After the formation process, development residues 130 may exist on the substrate 100. The development residues 130 may be undeveloped photoresist or developer residues. If the development residues 130 remains on the substrate 100 or the photoresist pattern 120, defects may occur during manufacturing the semiconductor device.

Referring to FIG. 4, the above-described cleaning composition according to the exemplary embodiments may be applied to the substrate 100 or immerse it. Accordingly, the development residues 130 formed on the substrate 100 or the photoresist pattern 120 may be removed.

The cleaning step may be performed by applying the above-described cleaning composition according to the exemplary embodiments to the substrate 100 under commonly known cleaning conditions.

In some embodiments, the temperature during the cleaning may be generally 25° C. to 70° C., and preferably 25° C. to 50° C. A residence time of the substrate 100 when immersed in the cleaning composition may be about 5 seconds to 10 minutes, and preferably 10 seconds to 5 minutes.

In some embodiments, the cleaning step may perform a first cleaning using deionized water to remove the development residues, followed by a second cleaning using the above-described cleaning composition according to the exemplary embodiments.

As described above, the cleaning composition includes the alcohol solvent and the alloy particles in the predetermined content, such that the temporal stability and purity may be improved. Accordingly, the occurrence of defects in the semiconductor device may be suppressed and the production yield may be improved.

The cleaning composition according to the exemplary embodiments may be used in a cleaning process for an electronic device such a semiconductor or display in addition to the process of forming a pattern using the photoresist, and may be used in other fields where the alcohol solvent is used.

Hereinafter, experimental examples including specific examples and comparative examples are proposed to facilitate understanding of the present invention. However, the following examples are only given for illustrating the present invention and are not intended to limit the appended claims. It will be apparent those skilled in the art that various alterations and modifications are possible within the scope and spirit of the present invention, and such alterations and modifications are duly included in the appended claims.

### EXAMPLES AND COMPARATIVE EXAMPLES

Cleaning compositions of the examples and comparative examples were prepared by mixing the components described in Table 1 (Examples) and Table 2 (Comparative Examples) according to the respective contents thereof. The contents of each component are indicated based on the total weight of the cleaning composition.

TABLE 1

| Division | Metal particles | Alcohol solvent |
|---|---|---|
| Example 1 | A-1 | B-3 |
| | (0.01 ppt) | (Balance) |
| Example 2 | A-1 | B-3 |
| | (0.05 ppt) | (Balance) |
| Example 3 | A-1 | B-3 |
| | (10 ppt) | (Balance) |
| Example 4 | A-1 | B-3 |
| | (0.1 ppb) | (Balance) |
| Example 5 | A-1 | B-3 |
| | (0.5 ppb) | (Balance) |
| Example 6 | A-1 | B-1 |
| | (10 ppt) | (Balance) |
| Example 7 | A-1 | B-2 |
| | (10 ppt) | (Balance) |
| Example 8 | A-1 | B-3 (50 wt %) and |
| | (10 ppt) | B-4 (Balance) |
| Example 9 | A-2 | B-4 |
| | (10 ppt) | (Balance) |
| Example 10 | A-2 | B-5 |
| | (10 ppt) | (Balance) |
| Example 11 | A-2 | B-3 (50 wt %) and |
| | (10 ppt) | B-4 (Balance) |
| Example 12 | A-1 | B-3 |
| | (0.001 ppt) | (Balance) |
| Example 13 | A-3 | B-3 |
| | (0.01 ppt) | (Balance) |

TABLE 2

| Division | Metal particles | Alcohol solvent |
|---|---|---|
| Comparative Example 1 | — | B-1 |
| | | (100 wt %) |
| Comparative Example 2 | — | B-2 |
| | | (100 wt %) |
| Comparative Example 3 | — | B-3 |
| | | (100 wt %) |
| Comparative Example 4 | A-4 | B-3 |
| | (10 ppt) | (Balance) |

The specific component names described in Tables 1 and 2 are as follows.

### Metal Particles

1) A-1: Al (50 wt %)-Ni (50 wt %) (manufactured by Sigma-Aldrich)
2) A-2: Ni (45 wt %)-Fe (55 wt %) (manufactured by Sigma-Aldrich)
3) A-3: 30 wt % Pt₃Co on Carbon (manufactured by Sigma-Aldrich)
4) A-4: Cu (manufactured by Sigma-Aldrich)

### Alcohol Solvent

1) B-1: Ethanol (manufactured by Sigma-Aldrich)
2) B-2: 1-Propanol (manufactured by Sigma-Aldrich)
3) B-3: 2-Propanol (manufactured by Sigma-Aldrich)
4) B-4: 1-Butanol (manufactured by Sigma-Aldrich)
5) B-5: 1-Pentanol (manufactured by Sigma-Aldrich)

### Experimental Example (Evaluation of Impurity Content According to Oxidation Reaction)

### (1) Initial Evaluation

Immediately after preparing the cleaning compositions according to the examples and comparative examples, the content (ppb) of aldehyde or ketone included in each cleaning composition was analyzed using Agilent's 7890A/5975C GC-MS equipment and Agilent's CP-Volamine (60 m, 0.32 mm) column.

Pre-quantified standard materials (aldehyde and ketone) were prepared, and the aldehyde or ketone detected in the cleaning composition was quantified by comparing it with a peak area of the standard material.

### (2) Temporal Evaluation

The content (ppb) of aldehyde or ketone included in each cleaning composition was analyzed in the same manner as the initial evaluation, except that the cleaning compositions according to the examples and comparative examples were stored at 60° C. for 90 days, then analysis was performed.

### (3) Evaluation of Temporal Stability

According to the following equation, a content change rate of aldehyde or ketone was calculated, and the temporal stability of the cleaning compositions according to the examples and comparative examples was evaluated, respectively.

$$Content increase rate of aldehyde or ketone ( \% ) = ( ( Content of aldehyde or ketone upon temporal evaluation ) - ( Content of aldehyde or ketone upon initial evaluation ) ) / ( Content of aldehyde or ketone upon initial evaluation ) \times 100$$

### <Standards for Evaluation>

◯: Content increase rate of aldehyde or ketone is 20% or less
Δ: Content increase rate of aldehyde or ketone is greater than 20% and less than 40%
x: Content increase rate of aldehyde or ketone is 40% or more

Evaluation results are described in Table 3 (Examples) and Table 4 (Comparative Examples) together, and aldehydes or ketones formed as each alcohol solvent included in the examples and comparative examples is oxidized are described as analysis targets (content measurement targets), and the content of aldehyde or ketone (ppb) is indicated based on the total weight of the cleaning composition.

In the case of Examples 8 and 11 including two types of alcohol solvents, a material formed in a larger amount is described.

TABLE 3

| | Content | Initial | Temporal | |
|---|---|---|---|---|
| | measurement | evaluation | evaluation | Temporal |
| Division | target | (ppb) | (ppb) | stability |
| Example 1 | C-3 | 1125 | 1084 | ∘ |
| Example 2 | C-3 | 1150 | 1107 | ∘ |
| Example 3 | C-3 | 1138 | 1071 | ∘ |
| Example 4 | C-3 | 1132 | 958 | ∘ |
| Example 5 | C-3 | 1146 | 962 | ∘ |
| Example 6 | C-1 | 1623 | 1603 | ∘ |
| Example 7 | C-2 | 1304 | 1295 | ∘ |
| Example 8 | C-3 | 552 | 549 | ∘ |
| Example 9 | C-4 | 878 | 571 | ∘ |
| Example 10 | C-5 | 854 | 856 | ∘ |
| Example 11 | C-3 | 591 | 587 | ∘ |
| Example 12 | C-3 | 1135 | 1382 | Δ |
| Example 13 | C-3 | 1137 | 1371 | Δ |

TABLE 4

| | Content | Initial | Temporal | |
|---|---|---|---|---|
| | measurement | evaluation | evaluation | Temporal |
| Division | target | (ppb) | (ppb) | stability |
| Comparative | C-1 | 1617 | 2875 | x |
| Example 1 | | | | |
| Comparative | C-2 | 1326 | 2039 | x |
| Example 2 | | | | |
| Comparative | C-3 | 1136 | 1828 | x |
| Example 3 | | | | |
| Comparative | C-3 | 1141 | 1711 | x |
| Example 4 | | | | |

The specific component names described in Tables 3 and 4 are as follows.
1) C-1: Acetaldehyde
2) C-2: Propionaldehyde
3) C-3: Acetone
4) C-4: Butyraldehyde
5) C-5: Pentanaldehyde

Referring to Tables 3 and 4, in the cleaning compositions of the examples including the alloy particles in a content of greater than 0 and less than 1 ppb based on the total weight of the composition, the content increase rate of the aldehyde or ketone was 20% or less, or greater than 20% and less than 40%, such that the temporal stability was improved.

In the cleaning compositions of the comparative examples including no alloy particles or a single metal, the content of the aldehyde or ketone upon temporal evaluation was increased by 40% or more compared to the initial evaluation, such that the temporal stability was deteriorated.

Accordingly, it can be seen that in the cleaning composition including the alloy particles in a content of greater than 0 and 1 ppb or less based on the total weight of the composition, the formation of impurities by the oxidation reaction of the alcohol solvent is suppressed, and the production yield may be improved when manufacturing the electronic device such a semiconductor or display.

What is claimed is:

1. A cleaning composition comprising:
an alcohol solvent; and
alloy particles,
wherein a content of the alloy particles is greater than 0 and 1 ppb or less based on a total weight of the composition.

2. The cleaning composition according to claim 1, wherein the alcohol solvent comprises an alcohol having 2 to 5 carbon atoms.

3. The cleaning composition according to claim 1, wherein the alcohol solvent comprises at least one selected from the group consisting of ethanol, 1-propanol, 2-propanol, 1-butanol and 1-pentanol.

4. The cleaning composition according to claim 1, wherein the alcohol solvent comprises an alcohol having a boiling point of 110° C. or lower.

5. The cleaning composition according to claim 1, wherein the alloy particles comprise at least two selected from the group consisting of aluminum, nickel, iron, copper, zinc, cobalt, manganese, chromium, vanadium, titanium, zirconium, niobium, molybdenum, ruthenium, rhodium, silver and platinum.

6. The cleaning composition according to claim 1, wherein the alloy particles comprise at least two selected from the group consisting of nickel, aluminum, copper, iron, platinum and cobalt.

7. The cleaning composition according to claim 1, wherein the alloy particles comprise nickel, and further comprise at least one selected from the group consisting of aluminum, iron and copper.

8. The cleaning composition according to claim 1, wherein the alloy particles comprise aluminum, and further comprise at least one selected from the group consisting of nickel, iron and copper.

9. The cleaning composition according to claim 1, wherein the content of the alloy particles is 0.01 ppt or more and 0.5 ppb or less based on the total weight of the composition.

10. The cleaning composition according to claim 1, wherein the content of the alloy particles is 0.05 ppt or more and 0.1 ppb or less based on the total weight of the composition.

11. The cleaning composition according to claim 1, wherein the composition comprises a balance of the alcohol solvent.

12. A method of forming a photoresist pattern comprising:
forming a photoresist film on a substrate;
partially removing the photoresist film to form a photoresist pattern; and
cleaning the substrate on which the photoresist pattern is formed using the cleaning composition according to claim 1.
